(19) United States
(12) Patent Application Publication
(10) Pub. No.: US 2026/0246227 A1
(43) Pub. Date: Aug. 20, 2026

(54) OPTICAL FIBER DEVICE, METHOD FOR MANUFACTURING OPTICAL FIBER DEVICE, AND LASER DEVICE

(71) Applicant: SHIMADZU CORPORATION, Kyoto-shi (JP)

(72) Inventors: Tomoyuki HIROKI, Kyoto-shi (JP); Minoru YAMADA, Kyoto-shi (JP); Junki SAKAMOTO, Kyoto-shi (JP)

(21) Appl. No.: 19/165,399

(22) PCT Filed: Mar. 7, 2024
(86) PCT No.: PCT/JP2024/008656

§ 371 Date: Dec. 8, 2025

(30) Foreign Application Priority Data
Mar. 16, 2023 (JP) 2023-041702

(51) Int. Cl. H01S 5/02251; G02B 6/02; G02B 6/42; H01S 5/02234

(52) U.S. Cl. CPC H01S 5/02251; G02B 6/02009; G02B 6/4296; H01S 5/02234

(57) ABSTRACT

An optical fiber device (1) includes an optical fiber (21), an end cap (20), and a light-transmissive resin (10). The end cap (20) has a first end face (201) and a second end face (202) opposite to each other. The first end face (201) of the end cap (20) is joined to an end face (211) of the optical fiber (21). The resin (10) has a connection surface (101) and is disposed so as to cover the second end face (202) of the end cap (20) with a part of the connection surface (101).

### TECHNICAL FIELD

The present disclosure relates to an optical fiber device, a method for manufacturing an optical fiber device, and a laser device, and more particularly, to a structure for improving the reliability of an optical fiber used in a laser device.

### BACKGROUND ART

In a device that guides laser light with an optical fiber (hereinafter also referred to as a “laser device”), an input end face where the laser light enters and an output end face where the laser light exits are interfaces between a core that propagates the laser light and the outside air. Therefore, burnout of a coating and burnout due to attached foreign matter are likely to occur. If the function of the optical fiber becomes abnormal due to such burnout, the operation of the laser device may also become abnormal. Therefore, suppressing the occurrence of such burnout is important for ensuring the reliability of the laser device.

To prevent such burnout, a technique is known in which glass is fused to the end face of an optical fiber for protection. Japanese Unexamined Patent Application Publication No. 2004-253783 (Patent Literature 1) discloses a laser module that prevents dust collection by providing a glass block on the input end face of an optical fiber. A configuration in which a glass end cap is fused to the end face of an optical fiber is also known. By fusing glass to the end face of the optical fiber as described above, burnout caused by dust collection can be reduced.

### CITATION LIST

### Patent Literature

Patent Literature 1: Japanese Unexamined Patent Application Publication No. 2004-253783
Patent Literature 2: Japanese Unexamined Patent Application Publication No. H5-3377

### SUMMARY OF INVENTION

### Technical Problem

However, it is difficult to fuse glass larger than the fiber diameter to the end face of an optical fiber. Also, when using an end cap, it is necessary to process glass with a special shape that matches the divergence angle of the optical fiber. Therefore, especially as the energy of the laser light becomes higher, a special large-diameter end cap is required, which increases the cost.

Therefore, there has been a demand for improving the reliability of an optical fiber and a laser device using the optical fiber by protecting the end face of the optical fiber with a simple configuration.

### Solution to Problem

An optical fiber device according to an aspect of the present disclosure includes an optical fiber, an end cap, and a light-transmissive resin. The end cap has a first end face and a second end face opposite to each other, and the first end face is joined to an end face of the optical fiber. The resin has a connection surface, and is disposed so as to cover the second end face of the end cap with a part of the connection surface.

A method for manufacturing an optical fiber device according to another aspect of the present disclosure includes a step of preparing an optical fiber having an end cap fused to at least one end face thereof, a step of enclosing a periphery of a second end face opposite to a first end face to which the optical fiber is fused in the end cap with a fence, and a step of covering the second end face within the fence with a light-transmissive resin.

A laser device according to still another aspect of the present disclosure includes a laser light source, an optical fiber device, and an optical system. The laser light source outputs laser light. The optical fiber device transmits the laser light emitted from the laser light source. The optical system optically couples the laser light to the optical fiber device. The optical fiber device includes an optical fiber, an end cap, and a light-transmissive resin. The end cap has a first end face and a second end face opposite to each other, and the first end face is joined to an end face of the optical fiber. The resin has a connection surface, and is disposed so as to cover the second end face of the end cap with a part of the connection surface.

### Advantageous Effects of Invention

According to the optical fiber device of the present disclosure, the reliability of the optical fiber and a laser device using the optical fiber can be improved by protecting the end face of the optical fiber with a simple configuration.

### BRIEF DESCRIPTION OF DRAWINGS

FIG. 1 is a functional block diagram of an optical lattice atomic clock to which a laser device of an embodiment is applied.

FIG. 2 is a conceptual diagram of an optical lattice.

FIG. 3 is a diagram for explaining a configuration of a laser device of an optical fiber device.

FIG. 4 is a cross-sectional view of the optical fiber device.

FIG. 5 is a flowchart showing a process related to manufacturing the optical fiber device.

### DESCRIPTION OF EMBODIMENTS

Hereinafter, embodiments of the present disclosure will be described in detail with reference to the drawings. In the drawings, the same or corresponding parts are denoted by the same reference signs, and a description thereof will not be repeated.

### Overall Configuration of Optical Lattice Clock

The laser device according to the present embodiment is a visible light laser device or a high-power laser device. First, a configuration of an atomic clock device 100 will be described as an example of a device to which the laser device according to the present embodiment is applied.

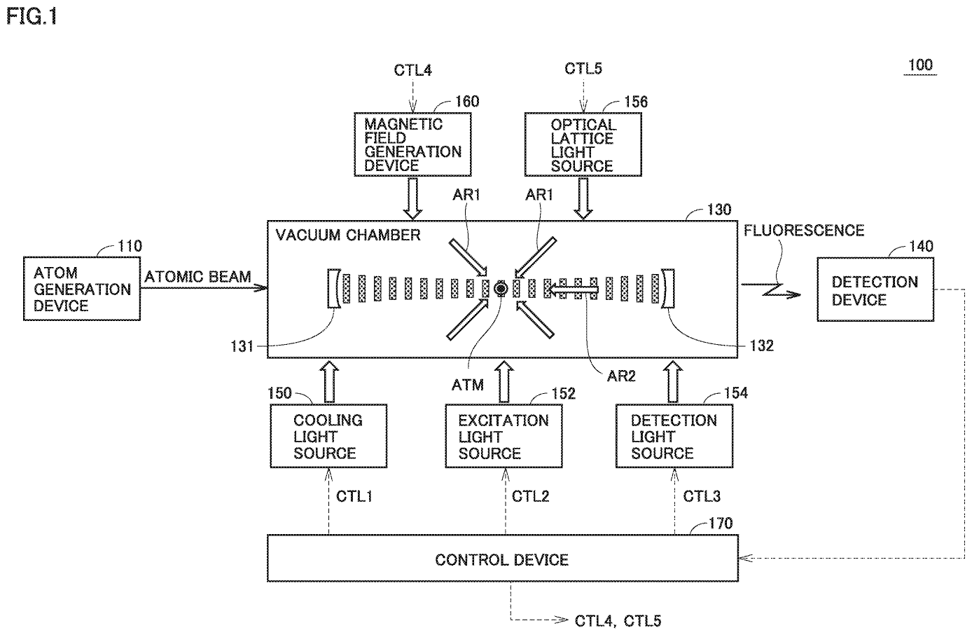

FIG. 1 is a functional block diagram of an atomic clock device 100 to which a laser device according to the embodiment is applied. The atomic clock device 100 in FIG. 1 is an optical lattice atomic clock (optical lattice clock).

Referring to FIG. 1, the atomic clock device 100 includes an atom generation device 110, a vacuum chamber 130, a detection device 140, a plurality of laser devices, a magnetic field generation device 160, and a control device 170. The plurality of laser devices include a cooling light source 150, an excitation light source 152, a detection light source 154, and an optical lattice light source 156.

The atom generation device 110 emits a high-velocity atomic gas as an atomic beam. The atomic beam emitted from the atom generation device 110 is guided into the vacuum chamber 130.

The cooling light source 150 irradiates the atomic beam emitted from the atom generation device 110 with three-dimensionally opposing laser light (arrows AR1, AR2 in FIG. 1) within the vacuum chamber 130. The “laser light” may also be generally referred to as a “laser,” “optical laser,” or “laser beam.” This cooling laser light reduces the velocity of the atoms and cools them to a predetermined temperature.

Further, a pair of opposing mirrors 131, 132 is provided in the vacuum chamber 130. When laser light controlled to a specific wavelength (magic wavelength) is emitted from the optical lattice light source 156 between the opposing mirrors 131, 132, a standing wave is generated by the laser light between the mirror 131 and the mirror 132.

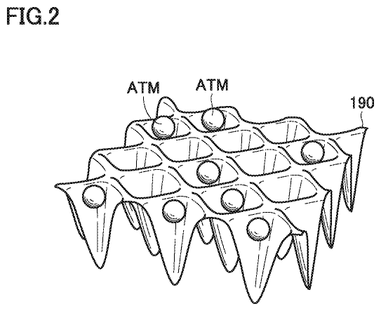

Generally, an atom is polarized in an electric field to generate an induced dipole. This dipole interacts with the electric field. As a result, in a spatially non-uniform laser electric field, the electric potential for the atom becomes a minimum at a maximum point of the electric field strength, and the atom is captured (trapped) at that position. As described above, when a standing wave of laser light is generated between the mirrors 131, 132, the atoms are trapped at the antinodes of the standing wave. When this standing wave is combined three-dimensionally, an “optical lattice” in which atoms are arranged at half-wavelength intervals is realized. FIG. 2 conceptually shows this optical lattice. In FIG. 2, an optical lattice 190 generated by the laser light is conceptually a spatial interference fringe in which potential wells of electric potential are formed at regular intervals, and atoms ATM are trapped in the wells.

If an atom has momentum (velocity), the resonance frequency may shift due to the Doppler effect, which may reduce the accuracy of the measured time. By decelerating the atoms ATM in the atomic beam using the laser light from the cooling light source 150 and trapping the atoms ATM using the optical lattice 190 as shown in FIG. 2, it becomes possible to search for the resonance frequency of the atoms in a stationary state.

The magnetic field generation device 160 applies a magnetic field to the moving atoms ATM by passing a current through an electromagnetic coil (not shown) disposed around the mirrors 131, 132 in the vacuum chamber 130. The applied magnetic field controls the energy level of the atoms ATM and contributes to various types of atomic cooling.

The excitation light source 152 irradiates the trapped atoms ATM with pulsed laser light to excite an energy transition of the atoms ATM.

The detection light source 154 irradiates the atoms ATM with detection laser light after the energy level of the atoms ATM is excited by the excitation light source 152. The laser light irradiated from the detection light source 154 generates fluorescence having an intensity proportional to the energy transition probability of the atoms.

The detection device 140 receives the fluorescence generated by the detection light source 154 and detects the intensity of the received fluorescence. The detection device 140 outputs a transition probability spectrum, which is represented by the detected fluorescence intensity and depends on the excitation laser frequency, to the control device 170.

The control device 170 is configured to include, for example, a CPU (Central Processing Unit), a memory, and an input/output interface (all not shown), and comprehensively controls each device of the atomic clock device 100. The control device 170 specifies the resonance frequency of the atoms ATM from the transition probability spectrum received from the detection device 140, and measures time based on the resonance frequency. Further, the control device 170 stabilizes the frequency of the laser light irradiated from the excitation light source 152 based on the resonance frequency obtained by calculation.

In the laser device of such an optical lattice atomic clock, laser light of a short wavelength (for example, 496 nm) is used. As will be described in detail later, the end face of an optical fiber that propagates such short-wavelength laser light has a high dust-collecting effect and is prone to burnout.

Also, in a high-power laser device used in a laser processing machine or the like, since the optical density at the optical fiber end face is high, burnout is likely to occur, similar to the laser device of the optical lattice atomic clock.

Therefore, in order to protect the end face of the optical fiber and ensure the long-term reliability of the laser device and a device including the laser device (for example, an optical lattice atomic clock or a high-power laser device), an optical fiber device 1 having a configuration for protecting the end face of the optical fiber is used in the laser device 200 according to the present embodiment.

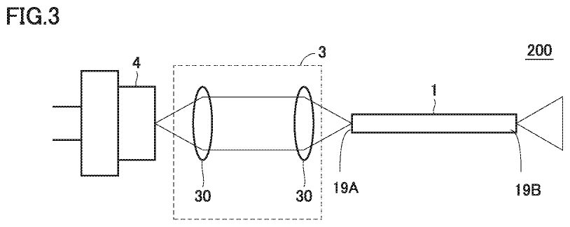

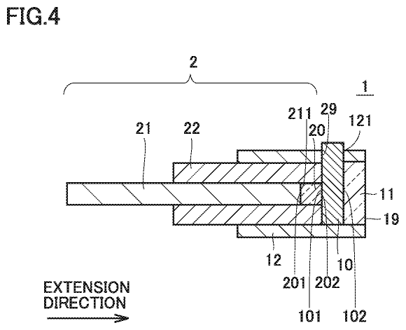

Next, the configurations of the laser device 200 and the optical fiber device 1 according to the present embodiment will be described with reference to FIGS. 3 and 4.

### Configuration of Laser Device

FIG. 3 is a diagram for explaining a configuration of the laser device 200 according to the present embodiment. As shown in FIG. 3, the laser device 200 includes a laser light source 4, an optical system 3, and an optical fiber device 1.

The laser light source 4 outputs laser light. The optical system 3 includes, for example, a lens 30, and optically couples the laser light to the optical fiber using the lens 30.

The optical fiber device 1 transmits the laser light emitted from the laser light source 4. The optical fiber device 1 includes an input end face 19A on the side where the laser light source is incident, and an output end face 19B on the side where it is emitted. The optical fiber device 1 has a configuration in which the end face of the optical fiber is protected from the outside air at at least one of the input end face 19A and the output end face 19B, as will be described in detail with reference to FIG. 4. The laser light emitted from the output end face 19B of the optical fiber device 1 is used according to the application of the device including the optical fiber device 1. For example, the laser light is used for time measurement or laser processing.

### Overview of Configuration of Optical Fiber Device

FIG. 4 is a cross-sectional view of the optical fiber device, and more specifically, a cross-sectional view of the optical fiber device 1 near at least one end face of the input end face 19A and the output end face 19B of the optical fiber device 1. Hereinafter, at least one end face of the input end face 19A and the output end face 19B of the optical fiber device 1 is referred to as an end face 19.

The optical fiber device 1 includes a capped fiber 2, a resin 10, a glass plate 11, and a fence 12.

The capped fiber 2 includes an end cap 20, an optical fiber 21, and a ferrule 22. The capped fiber 2 has an end face 29. The end face 29 includes a second end face 202 of the end cap 20, which will be described later, and an end face of the ferrule 22.

The optical fiber 21 includes a core that propagates laser light, a cladding surrounding the core, and a coating covering the cladding. In one embodiment, the optical fiber 21 is a single-mode fiber. A single-mode fiber is a fiber with a core diameter of 10 μm or less. A single-mode fiber typically has a diameter of about 125 μm. Single-mode fibers are used, for example, in devices where it is desired to maintain the coherence of the laser light, such as optical lattice clocks and analytical instruments. In another embodiment, the optical fiber 21 is a multi-mode fiber. A multi-mode fiber has a large laser light diameter and can couple a large amount of laser light, so high output is possible. Therefore, multi-mode fibers are often used in laser processing machines that do not require maintaining the coherence of the laser light but require high output.

The end cap 20 has a first end face 201 and a second end face 202 opposite to each other. The first end face 201 is joined to an end face 211 of the optical fiber 21 by fusion splicing. The end cap 20 includes glass. In one embodiment, the end cap 20 is made of glass.

Laser light has a property of diverging when it is output from the end face 211 of the optical fiber 21. However, immediately after the laser light is output from the end face 211, the beam diameter is small and the beam density is high, so it is preferable to isolate the end face 211 from the air. Therefore, by fusing a glass end cap 20 to the end face 211, the laser light can be isolated from the air until the beam diameter expands to some extent within the end cap 20 and the beam density decreases.

Since glass has high light transmittance, light absorption within the glass is unlikely to occur even when laser light is transmitted. Therefore, by using the end cap 20 including glass, even if high-optical-density laser light is transmitted, the inside of the end cap 20 is not damaged and can maintain light transmissivity. It is preferable to use glass with a low absorption rate for short wavelengths, such as silica glass, for the end cap 20. Therefore, by using the end cap 20 including silica glass, even if short wavelengths are transmitted, the inside of the end cap 20 is not damaged and can maintain light transmissivity.

Typically, the end cap 20 has the same diameter as the diameter of the cladding of the optical fiber 21. With this configuration, fusion splicing of the optical fiber 21 and the end cap 20 is relatively easy. By joining the first end face 201 of the end cap 20 to the end face 211 of the optical fiber 21, transmitting the laser light through the end cap 20, and expanding the beam diameter, the optical density at the second end face 202 of the end cap 20 becomes lower than the optical density at the end face 211 of the optical fiber 21.

The ferrule 22 is a cylinder having a cylindrical outer diameter and a hole in the center for passing the optical fiber 21, provided for terminating the optical fiber. In the example of FIG. 4, the ferrule 22 is installed so as to surround the optical fiber 21 with the end cap 20 joined thereto. As a result, when the end face 19 is the output end face 19B, the laser light propagated through the core of the optical fiber 21 is emitted only from the second end face 202 of the end cap 20. Also, when the end face 19 is the input end face 19A, the laser light is incident only from the second end face 202 of the end cap 20 and is propagated through the core of the optical fiber 21.

The resin 10 is a light-transmissive resin disposed so as to cover the second end face 202 of the end cap 20. In one embodiment, the resin 10 preferably includes a silicone-based resin with high light transmittance and high heat resistance. As a more specific example, the resin 10 is made of a silicone-based resin.

The resin 10 has an end face 101 to be joined to the end cap 20, and an end face 102 opposite to the end face 101. The end face 101 corresponds to an embodiment of a “connection surface.” The resin 10 covers the second end face 202 of the end cap 20 with a part of the end face 101. In this way, by joining the resin 10 to the end cap 20 and expanding the beam diameter by transmitting the laser light through the resin 10, the optical density at the end face 102 of the resin 10 becomes lower than the optical density at the second end face 202 of the end cap 20.

The glass plate 11 is disposed so as to sandwich the resin 10 with the end cap 20. The glass plate 11 is used to make the thickness of the resin 10 uniform and to make the end face 102 of the resin 10 a flat surface. In this specification, unless otherwise specified, “thickness” refers to the dimension in the extension direction of the optical fiber 21 (see the arrow in FIG. 4). The extension direction of the optical fiber more specifically refers to the extension direction of the end of the optical fiber 21. The glass plate 11 also serves to protect the resin 10. For example, the glass plate 11 suppresses the resin 10 from being scraped off or deformed when a mechanical shock is applied to the end face of the optical fiber device 1.

The fence 12 surrounds the periphery of the second end face 202 of the end cap 20. In one embodiment, the fence 12 is a metal cylinder having a hole with the same diameter as the outer diameter of the capped fiber 2 (in the example of FIG. 4, the outer diameter of the ferrule 22). The fence 12 helps the resin 10 to be formed in an appropriate shape when the resin 10 is joined to the end cap. Specifically, the fence 12 is used as a mechanical cover to prevent the resin from flowing out to unnecessary places when the resin 10 is sandwiched by the glass plate 11. This makes it possible to easily cover the entire surface of the second end face 202 of the end cap 20 while preventing the resin 10 from adhering to parts other than the end face 29 of the capped fiber 2.

It is preferable that a hole 121 is provided in the fence 12. The hole 121 is provided to allow a part of the excess resin 10 in the fence 12 and/or air bubbles generated during the curing of the resin 10 to escape into the hole 121 or to the outside of the fence 12 when the resin 10 is sandwiched by the glass plate 11.

As described above, by joining the end cap 20 to the optical fiber 21, a capped fiber 2 is formed. Further, by joining the resin 10 to the capped fiber 2, an optical fiber device 1 is formed.

### Comparison with Conventional Laser Devices

In a laser device that guides laser light using an optical fiber, at the input end face where the laser light enters and the output end face where the laser light exits, burnout of the coating and burnout caused by attached foreign matter are likely to occur. This is because at the input end face or the output end face of the optical fiber, the core that propagates the laser light is exposed without being covered by the cladding and the coating in order to input or output the laser light. When the core with high optical density is exposed, surrounding structures such as the coating may burn out, or small substances in the outside air may adhere and burn out due to the dust-collecting effect.

In particular, in a high-power fiber-coupled laser device (also referred to as a “high-power laser device” in this specification) that guides high-energy laser light, the optical density at the input and output end faces of the optical fiber becomes even higher, and burnout of surrounding structures such as the coating and burnout due to the dust-collecting effect become even more likely to occur.

If the optical fiber becomes abnormal due to such burnout, the laser device itself may not be able to operate normally. Therefore, reducing the optical density of the end face exposed to the outside air at the input and output end faces is important for preventing burnout of the end faces and maintaining the reliability of the optical fiber and the laser device.

From the above viewpoints, a technique is known in which burnout is prevented by fusing a glass called an end cap to the end face of an optical fiber. In this specification, unless otherwise specified, “end cap” means an end cap formed of a material including glass (typically, a glass end cap).

However, when using an end cap, it is necessary to use one with a shape corresponding to the beam divergence angle when the laser light is emitted from the core of the optical fiber. The “beam divergence angle” is also generally referred to as “beam divergence angle” or “Numerical Aperture (NA).” In particular, the higher the energy of the laser light output from the optical fiber, the more a special large-diameter end cap and its fusion splicing technology are required, which further increases the cost.

In particular, for visible laser light, especially laser light with a wavelength of 500 nm or less, damage to the end face of the optical fiber due to a unique dust-collecting effect is likely to occur even in a low-power device with a laser output of 50 mW or less. Therefore, a hermetic package with a controlled atmosphere, as described in Patent Literature 1, is often used. However, manufacturing a hermetic package requires strict management of the manufacturing process and selection of members considering outgassing from the materials inside the hermetic package, which increases the manufacturing cost. Although Patent Literature 1 also discloses a technique of fusing a glass plate to the end face of an optical fiber instead of a hermetic package, it is difficult to fuse glass larger than the fiber diameter (typically 125 μm) to the optical fiber. For example, if a thermal load is applied to fuse an optical fiber and an object with a different diameter from the optical fiber (for example, glass), problems such as the characteristics of the optical fiber changing due to an excessive thermal load being applied to the optical fiber side due to the difference between the heat capacity of the optical fiber and the heat capacity of the object with a different diameter occur. Therefore, it is necessary to optimize the fusion splicing conditions and/or prepare a special jig for fusion splicing.

As a technique similar to the technique for preventing burnout of the optical fiber end face, Japanese Unexamined Patent Application Publication No. H5-3377 (Patent Literature 2) discloses a technique for reducing the energy density of laser light by providing a resin-made end-face-destruction-preventing layer on the light-emitting end face of a laser diode. However, even if resin is directly applied to the end face of the optical fiber, the resin will melt when using short-wavelength laser light as described above.

In the optical fiber device 1 according to the present embodiment, as detailed in FIG. 4, the first end face 201 of the end cap 20 is joined to the end face of the optical fiber 21, and the opposite second end face 202 of the end cap 20 is further covered with the light-transmissive resin 10. As a result, the optical density can be further reduced by the resin 10 after being reduced by the end cap 20. Therefore, the dust-collecting effect at the end face 211 of the optical fiber 21 can be reduced, and the long-term reliability of the optical fiber can be improved. Accordingly, a highly reliable fiber-coupled laser device can be realized without preparing a special large-diameter end cap or performing airtight management.

### Reduction of Optical Density by End Cap and Resin in Optical Fiber Device

Next, the reduction of optical density by the end cap 20 and the resin 10 in the optical fiber device 1 according to the present embodiment will be described.

In this specification, an end face exposed to the outside air in the optical fiber 21 in a state where neither the end cap 20 nor the resin 10 is provided is referred to as an end face A, an end face exposed to the outside air in the capped fiber 2 in a state where the end cap 20 is joined to the optical fiber 21 but the resin 10 is not provided is referred to as an end face B, and an end face exposed to the outside air in the optical fiber device 1 in a state where both the end cap 20 and the resin 10 are joined to the optical fiber 21 is referred to as an end face C. In this case, the optical density decreases in the order of the end face A, the end face B, and the end face C. The details will be described below.

By fusing the end cap 20 including glass to the end face 211 of the optical fiber 21, the beam density at the end face 29 of the capped fiber 2 when the end cap is fused can be made lower than the beam density at the end face 211 of the optical fiber 21 when the end cap 20 is not fused. This can improve the reliability of the optical fiber.

The thickness of the end cap 20 that can be used for reducing the beam density as described above is determined by the beam diameter at the second end face 202 of the end cap 20. More specifically, the end cap 20 is usually used in a thickness range where the beam diameter is about half or less of the diameter of the end cap 20. Therefore, for example, when the optical fiber 21 is a single-mode fiber with a diameter of 125 μm, it is appropriate to use an end cap 20 with a thickness that results in a beam diameter of 60 to 72 μm at the second end face 202 of the end cap 20. Here, the NA of the single-mode fiber is about 0.12. The optimal thickness of the end cap 20 calculated based on the above numerical values is about 0.25 mm or more and about 0.3 mm or less. Therefore, in the optical fiber device 1 according to the present embodiment, an end cap 20 with a thickness of preferably about 0.25 mm or more and about 0.3 mm or less is used.

When an end cap with a thickness of 0.3 mm is fused, the beam diameter at the second end face 202 of the end cap 20 becomes about 72 μm, and when the laser output is 40 mW, the beam density becomes about 1 kW/cm².

Therefore, by using the end cap 20, the optical density at the end face 29 of the capped fiber 2 is relaxed compared to the optical density at the end face 211 of the optical fiber 21. Specifically, the optical density at the end face 29 can be reduced to about 1 kW/cm². This reduces the possibility of burnout at the end face B exposed to the outside air and can suppress rapid deterioration around the end face 211 of the optical fiber 21. However, even when the capped fiber 2 is used, if the second end face 202 of the end cap 20 is exposed to the outside air, deposits will gradually accumulate on the second end face 202 due to the dust-collecting effect, especially when using laser light in the visible range. In this case, the deterioration around the end face 211 of the optical fiber 21 will proceed slowly.

Therefore, in order to further reduce the dust-collecting effect and improve the long-term reliability of the optical fiber, it is necessary to further reduce the beam density at the end face exposed to the outside air to about 1/10 or less (about 100 W/cm² or less). The numerical values for describing each part of the optical fiber device 1 according to the present embodiment are merely examples and should be understood to include errors that would be considered reasonable by a person skilled in the art. An error that would be considered reasonable by a person skilled in the art is, but is not limited to, for example, an error of 10% or less.

As described above, when the diameter and/or thickness of the end cap is increased, a special end cap and its fusion splicing technology are required, which increases the cost. Therefore, in the optical fiber device 1 according to the present embodiment, the beam density is reduced at a low cost by sealing the end face of the end cap 20 with the light-transmissive resin 10.

Here, when the laser output is 40 mW, if a distance of about 1.0 mm from the end face 211 of the optical fiber 21 (thickness in the extension direction of the optical fiber) is sealed, the beam density becomes 100 W/cm² or less.

As described above, the thickness of the end cap 20 is preferably about 0.25 mm or more and about 0.3 mm or less. Therefore, the thickness of the resin 10 is preferably about 0.7 mm or more and about 0.75 mm or less, which is obtained by subtracting the thickness of the end cap 20 from about 1.0 mm.

The thickness of the resin 10 is preferably determined based on the output of the optical laser. More specifically, it is preferable to increase the thickness of the resin 10 as the output of the optical laser increases. However, the larger the thickness of the resin 10, the greater the amount of absorption of the laser light in the resin 10, and the greater the thermal damage due to heat generation. Therefore, the thickness and material of the resin 10 are preferably configured such that the transmittance of the laser light is 99% or more. In other words, when the resin 10 has a thickness of 2 mm, it is preferable that the transmittance of light of a predetermined wavelength of 300 nm or more and 500 nm or less is 99% or more. This can suppress thermal damage due to absorption of the laser light in the resin 10.

Next, the diameter of the resin 10 will be described. The resin 10 has a cylindrical shape similar to the fence 12, except for the part that may protrude into the hole 121 or outside the fence 12 as described above. The diameter of the resin 10 indicates the diameter of the cylindrical part excluding the protruding part. That is, the diameter of the resin 10 is defined by the inner diameter of the fence 12. The diameter of the resin 10 is preferably larger than the diameter of the second end face 202 of the end cap 20. This allows the resin 10 to cover the entire second end face 202. The diameter of the second end face 202 of the end cap 20 is, for example, about 70 μm or more. Also, considering the divergence of the laser light within the resin 10, the laser light becomes about 100 W/cm² or less at the output-side end face 102 of the resin 10 when the beam diameter of the laser light is about 200 μm or more. Therefore, the diameter of the resin 10 is typically about 125 μm or more, and preferably about 200 μm or more. However, the shape of the resin 10 is not necessarily limited to a cylindrical shape, and may be, for example, a rectangular parallelepiped.

As described above, by using the resin 10, the optical density at the end face C can be reduced until the dust-collecting effect can be sufficiently suppressed. Therefore, in the optical fiber device 1, the part with high optical density is not exposed to the outside air. As a result, by using the optical fiber device 1 and a laser module including the optical fiber device 1, a laser device that can be used stably over a long period of time can be easily manufactured without using a special end cap or performing strict hermetic control. Therefore, special custom-made parts, hermetic parts, and/or jig and tool design are not necessary. Therefore, the design cost of the optical fiber device 1 and a laser device including the optical fiber device 1 can be reduced.

The glass plate 11 for sealing the resin 10 used in the optical fiber device 1 can be selected from general-purpose products that do not affect the performance of the laser light, depending on the wavelength and application of the laser light. Also, the fence 12 can be made from general-purpose metal parts. The resin 10 is also far cheaper than using a large-diameter glass end cap (for example, several hundred thousand yen). As described above, the manufacturing cost of the optical fiber device 1 can be reduced also from the aspect that the unit price of its materials is low.

### Method for Manufacturing Configuration of Optical Fiber Device

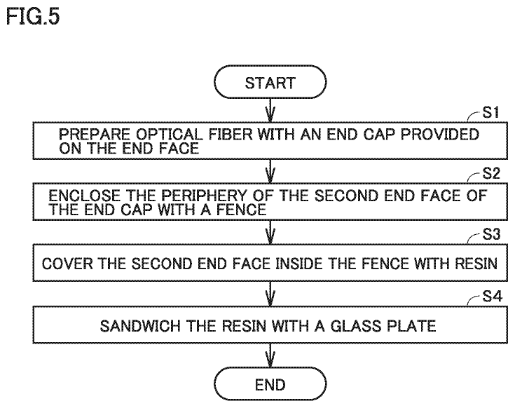

FIG. 5 is a flowchart showing a manufacturing process of the optical fiber device 1. Steps (hereinafter referred to as S) 1 to 4 are performed by a manufacturer of the optical fiber device 1 using appropriate machine tools for processing.
In S1, the manufacturer prepares an optical fiber 21 with an end cap 20 fused to at least one end face 19 (that is, a capped fiber 2). The manufacturer may manufacture the capped fiber 2 by himself by fusing the end cap 20 to the optical fiber 21, or may obtain it from another party.
In S2, the manufacturer encloses the periphery of the second end face 202, which is opposite to the first end face 201 to which the optical fiber 21 is fused in the end cap 20, with a fence 12. For example, the manufacturer inserts the end face 29 of the capped fiber 2 into the metal fence 12.
In S3, the manufacturer covers the second end face 202 inside the fence 12 with the light-transmissive resin 10. As a result, the second end face 202 is sealed with the light-transmissive resin 10. Specifically, the manufacturer applies an appropriate amount of the resin 10 to the second end face 202 inside the fence 12, or pours an appropriate amount of the resin 10 to cover the second end face 202 into the fence 12.
In S4, the manufacturer sandwiches the resin 10 poured into the fence 12 with a glass plate 11 from the side opposite to the end cap. This seals the resin 10 with the glass plate 11, reducing the possibility of damage due to mechanical shock. Also, the thickness of the resin 10 becomes substantially uniform. Typically, by leaving the resin 10 sandwiched by the glass plate 11, the resin 10 solidifies, and the optical fiber device 1 can be handled stably.

According to S1 to S4, the optical fiber 21 with high long-term reliability can be manufactured inexpensively and easily. Also, by incorporating the optical fiber device 1 manufactured as described above into a laser device, a laser device with high long-term reliability can be manufactured at a low cost.

### Aspects

It is understood by those skilled in the art that the plurality of exemplary embodiments described above are specific examples of the following aspects.
(Item 1) An optical fiber device according to one aspect includes an optical fiber, an end cap, and a light-transmissive resin. The end cap has a first end face and a second end face opposite to each other, and the first end face is joined to an end face of the optical fiber. The resin has a connection surface, and is disposed so as to cover the second end face of the end cap with a part of the connection surface.

According to the optical fiber device of Item 1, the optical density at the end face of the optical fiber is reduced by the end cap and further reduced by the light-transmissive resin. Therefore, the occurrence of burnout at the end portion of the optical fiber can be suppressed with a simple configuration of further covering the end cap with the resin. Therefore, the reliability of the optical fiber and a laser device using the optical fiber can be improved by protecting the end face of the optical fiber with a simple configuration.
(Item 2) In the optical fiber device according to Item 1, the end cap includes silica glass.

According to the optical fiber device of Item 2, even if short wavelengths are transmitted, the inside of the end cap 20 is not damaged and can maintain light transmissivity.
(Item 3) In the optical fiber device according to Item 1 or 2, the optical fiber includes a core that propagates laser light and a cladding surrounding the core. The end cap has the same diameter as the diameter of the cladding.

In the optical fiber device of Item 3, fusion splicing of the optical fiber and the end cap is relatively easy.
(Item 4) In the optical fiber device according to any one of Items 1 to 3, the optical fiber is a single-mode fiber.

In the optical fiber 21 of the optical fiber device of Item 4, the coherence of the laser light can be maintained.
(Item 5) In the optical fiber device according to any one of Items 1 to 4, the resin has a transmittance of 99% or more for light with a wavelength of 300 nm or more and 500 nm or less when the resin has a thickness of 2 mm.

According to the optical fiber device of Item 5, thermal damage due to absorption of the laser light in the resin can be suppressed.
(Item 6) In the optical fiber device according to any one of Items 1 to 5, the resin includes a silicone-based resin.

According to the optical fiber device of Item 6, a resin with high light transmittance and high heat resistance can be used.
(Item 7) In the optical fiber device according to any one of Items 1 to 6, when the extension direction of the optical fiber is a first direction, the combined thickness of the end cap and the resin in the first direction is 1.0 mm or less.

According to the optical fiber device of Item 7, the beam density can be appropriately reduced by the end cap and the resin, and the dust-collecting effect at the end face of the optical fiber device can be suppressed.
(Item 8) In the optical fiber device according to any one of Items 1 to 7, when the extension direction of the optical fiber is a first direction, the thickness of the resin in the first direction is 0.7 mm or more and 0.75 mm or less.

According to the optical fiber device of Item 8, when the thickness of the end cap is 0.25 mm or more and about 0.3 mm or less, the beam density can be appropriately reduced by the resin, and the dust-collecting effect at the end face of the optical fiber device can be suppressed.
(Item 9) In the optical fiber device according to any one of Items 1 to 8, when the extension direction of the optical fiber is a first direction, the thickness of the resin in the first direction is a thickness at which the density of a light beam entering the first end face is attenuated to 1/10 or less or 100 W/cm² or less and output from the second end face.

According to the optical fiber device of Item 9, the beam density can be appropriately reduced, and the dust-collecting effect at the end face of the optical fiber device can be suppressed.
(Item 10) In the optical fiber device according to any one of Items 1 to 9, the diameter of the resin is larger than the diameter of the second end face of the end cap.

According to the optical fiber device of Item 10, the cylindrical resin can cover the entire second end face.
(Item 11) In the optical fiber device according to any one of Items 1 to 10, the diameter of the resin is 125 μm or more.

According to the optical fiber device of Item 11, when the diameter of the second end face is 70 μm, the resin can cover the entire second end face.
(Item 12) In the optical fiber device according to any one of Items 1 to 11, the optical fiber device further includes a glass plate. The resin is sandwiched between the end cap and the glass plate.

According to the optical fiber device of Item 12, the end face of the resin can be smoothed and made flat by the glass plate. Also, the resin can be protected.
(Item 13) A method for manufacturing an optical fiber device according to another aspect includes a step of preparing an optical fiber with an end cap fused to at least one end face thereof, a step of enclosing a periphery of a second end face opposite to a first end face to which the optical fiber is fused in the end cap with a fence, and a step of covering the second end face within the fence with a light-transmissive resin.

According to the optical fiber device manufactured by the method for manufacturing an optical fiber device of Item 13, the optical density at the end face of the optical fiber is reduced by the end cap and further reduced by the light-transmissive resin. In this way, the occurrence of burnout at the end portion of the optical fiber can be suppressed by a simple manufacturing process of further covering the end cap with the resin. Therefore, according to the optical fiber device manufactured by the method for manufacturing an optical fiber device of Item 13, the end face of the optical fiber can be protected, and the reliability of a laser device using the optical fiber device can be improved.
(Item 14) The method for manufacturing an optical fiber device according to Item 13further includes a step of sandwiching the resin poured into the fence with a glass plate from the side opposite to the end cap.

According to the method for manufacturing an optical fiber device of Item 14, the end face of the resin can be smoothed and made flat. Also, the resin can be protected.
(Item 15) A laser device according to still another aspect includes a laser light source, an optical fiber device, and an optical system. The laser light source outputs laser light. The optical fiber device transmits the laser light emitted from the laser light source. The optical system optically couples the laser light to the optical fiber device. The optical fiber device includes an optical fiber, an end cap, and a light-transmissive resin. The end cap has a first end face and a second end face opposite to each other, and the first end face is joined to an end face of the optical fiber. The resin has a connection surface, and is disposed so as to cover the second end face of the end cap with a part of the connection surface.

In the optical fiber device of the laser device of Item 15, the optical density at the end face of the optical fiber is reduced by the end cap and further reduced by the light-transmissive resin. In this way, the occurrence of burnout at the end portion of the optical fiber is suppressed with a simple configuration of further covering the end cap with the resin. Therefore, the optical fiber device of the laser device of Item 15 has high long-term reliability.

The embodiments disclosed this time should be considered illustrative in all respects and not restrictive. The scope of the present disclosure is indicated by the claims rather than the description of the embodiments above, and all changes that come within the meaning and range of equivalency of the claims are intended to be embraced therein.

### REFERENCE SIGNS LIST

1 Optical fiber device, 2 Capped fiber, 3 Optical system, 4 Laser light source, 10 Resin, 11 Glass plate, 12 Fence, 18A to 18C Path, 19, 29, 101, 102, 211, A, B, C End face, 19A Input end face, 19B Output end face, 20 End cap, 21 Optical fiber, 22 Ferrule, 30, 220 Lens, 100 Atomic clock device, 110 Atom generation device, 121 Hole, 130 Vacuum chamber, 131, 132 Mirror, 140 Detection device, 150 Cooling light source, 152 Excitation light source, 154 Detection light source, 156 Optical lattice light source, 160 Magnetic field generation device, 170 Control device, 172 Memory, 173 Current control unit, 174 Input/output interface, 180 Beam splitter, 185 Laser detector, 190 Optical lattice, 195 Display device, 196 Input device, 200A, 200B Laser device, 201 First end face, 202 Second end face, 205 Semiconductor laser, 210 Laser diode, 230 Wavelength selection element, ATM Atom.

1. An optical fiber device, comprising:
an optical fiber;
an end cap having a first end face and a second end face opposite to each other, the first end face being joined to an end face of the optical fiber;
a light-transmissive resin having a connection surface, the resin being disposed so as to cover the second end face of the end cap with a part of the connection surface; and
a glass plate.
wherein the resin is sandwiched between the end cap and the glass plate.

2. The optical fiber device according to claim 1, wherein the end cap includes silica glass.

3. The optical fiber device according to claim 1, wherein
the optical fiber includes a core that propagates laser light and a cladding surrounding the core, and
the end cap has the same diameter as a diameter of the cladding.

4. The optical fiber device according to claim 1, wherein the optical fiber is a single-mode fiber.

5. The optical fiber device according to claim 1, wherein the resin has a transmittance of 99% or more for light with a wavelength of 300 nm or more and 500 nm or less when the resin has a thickness of 2 mm.

6. The optical fiber device according to claim 1, wherein the resin includes a silicone-based resin.

7. The optical fiber device according to claim 1, wherein, when an extension direction of the optical fiber is a first direction,
a combined thickness of the end cap and the resin in the first direction is 1.0 mm or less.

8. The optical fiber device according to claim 1, wherein, when an extension direction of the optical fiber is a first direction,
a thickness of the resin in the first direction is 0.7 mm or more and 0.75 mm or less.

9. The optical fiber device according to claim 1, wherein, when an extension direction of the optical fiber is a first direction,
a thickness of the resin in the first direction is a thickness at which a density of a light beam entering the first end face is attenuated to 1/10 or less or 100 W/cm² or less and output from the second end face.

10. The optical fiber device according to claim 1, wherein a diameter of the resin is larger than a diameter of the second end face of the end cap.

11. The optical fiber device according to claim 1, wherein a diameter of the resin is 125 μm or more.

12. (canceled)

13. A method for manufacturing an optical fiber device, the method comprising:
a step of preparing an optical fiber having an end cap fused to at least one end face thereof;
a step of enclosing a periphery of a second end face, which is opposite to a first end face to which the optical fiber is fused in the end cap, with a fence; and
a step of covering the second end face within the fence with a light-transmissive resin.

14. The method for manufacturing an optical fiber device according to claim 13, further comprising a step of sandwiching the resin poured into the fence with a glass plate from a side opposite to the end cap.

15. A laser device, comprising:
a laser light source that outputs laser light;
an optical fiber device that transmits the laser light emitted from the laser light source; and
an optical system that optically couples the laser light to the optical fiber device, wherein
the optical fiber device includes:
an optical fiber;
an end cap having a first end face and a second end face opposite to each other, the first end face being joined to an end face of the optical fiber; and
a light-transmissive resin having a connection surface, the resin being disposed so as to cover the second end face of the end cap with a part of the connection surface; and
a glass plate,
wherein the resin is sandwiched between the end cap and the glass plate.
